(19) United States
(12) Patent Application Publication
(10) Pub. No.: US 2021/0311688 A1
(43) Pub. Date: Oct. 7, 2021

(54) CONTEXTUAL SPEAKER ARRANGEMENT MAPPING

(71) Applicant: Bose Corporation, Framingham, MA (US)

(72) Inventors: Dion Isselhardt, Cottonwood Heights, UT (US); Lisa Lyman, Natick, MA (US); Adam Holladay, Salt Lake City, UT (US); Kevin Ernst, Pleasant Grove, UT (US)

(73) Assignee: Bose Corporation, Framingham, MA (US)

(21) Appl. No.: 16/841,837

(22) Filed: Apr. 7, 2020

(51) Int. Cl. G06F 3/16; H04S 7/00

(52) U.S. Cl. CPC G06F 3/162; H04S 7/30

(57) ABSTRACT

A computer-implemented method for manipulating simulated speaker arrangements is provided, including: (1) receiving a portion selection event corresponding to a portion of a simulated speaker arrangement displayed in a speaker arrangement pane of a GUI; (2) displaying a pop-up window, wherein the pop-up window includes an initial value of a property corresponding to the portion; (3) receiving a property adjustment event corresponding to the property; (4) displaying an updated value of the property based on the property adjustment event; (5) adjusting the simulated speaker arrangement based on the property adjustment event; (6) receiving a portion deselection event corresponding to an area of the GUI outside of the pop-up window; and (7) closing the pop-up window in response to the portion deselection event. The selection and/or deselection events may include a mouse-click, a mouse-over-event, or key-strokes. The portion may include an individual speaker, a rigging point, and/or multiple speakers.

### BACKGROUND

This disclosure generally relates to systems and methods for manipulating arrangements of speakers in a computer-implemented design and simulation environment.

### SUMMARY

This disclosure generally relates to systems and methods for manipulating arrangements of speakers in a computer-implemented design and simulation environment.

In one aspect, a computer-implemented method for manipulating one or more simulated speaker arrangements is provided. The method may include receiving a first portion selection event. The first portion selection event may be a mouse-click. The first portion selection event may be a mouse-over-event. The first portion selection event may include one or more key-strokes.

The first portion selection event may correspond to a portion of a first simulated speaker arrangement displayed in a speaker arrangement pane of a graphical user interface (“GUI”).

The method may further include displaying a first pop-up window. The first pop-up window may be displayed proximate to the portion of the first simulated speaker arrangement. The first pop-up window may include an initial value of a first property corresponding to the portion.

The method may further include receiving a first property adjustment event. The first property adjustment event may correspond to the first property. The method may further include displaying an updated value of the first property. The updated value may be based on the first property adjustment event. The method may further include adjusting the first simulated speaker arrangement based on the first property adjustment event.

The method may further include receiving a first portion deselection event. The first portion deselection event may correspond to an area of the GUI outside of the first pop-up window.

The method may further include closing the first pop-up window in response to the first portion deselection event. The first portion deselection event may be a mouse-click. The first portion deselection event may be a mouse-over-event. The first portion deselection event may include one or more key-strokes.

According to an example, the portion of the first simulated speaker arrangement may be a rigging point. The first property may be selected from a group consisting of x-position, y-position, z-position, box count, vertical angle, horizontal angle, and weight.

According to an example, the portion of the first simulated speaker arrangement may be a speaker. The first property is selected from a group consisting of box make, gain, first angle, and second angle.

According to an example, the portion of the first simulated speaker arrangement may be a plurality of speakers. The first property may be selected from a group consisting of box make, gain, first angle, and second angle.

According to an example, the method may further include adjusting an overhead simulation pane of the GUI based on the first property adjustment event. The overhead simulation pane may include a simulated overhead view of a first sound pressure generated by the first simulated speaker arrangement in a model environment.

According to an example, the method may further include adjusting a side simulation pane of the GUI based on the first property adjustment event. The side simulation pane may include a simulated side view of a first sound pressure generated by the first simulated speaker arrangement in a model environment.

According to an example the pop-up window may further include an initial value of a second property corresponding to the portion. The method may further include receiving a second property adjustment event corresponding to the second property. The method may further include displaying an updated value of the second property based on the second property adjustment event. The method may further include adjusting the first simulated speaker arrangement based on the second property adjustment event.

According to an example, the method may further include displaying, on a speaker arrangement selection pane of the GUI, a list of simulated speaker arrangements. The list may reference the first simulated speaker arrangement and a second simulated speaker arrangement. The method may further include receiving a first speaker arrangement selection event corresponding to the first simulated speaker arrangement. The method may further include displaying the first simulated speaker arrangement in the speaker arrangement pane of the GUI.

According to an example, the method may further include receiving a second speaker arrangement selection event corresponding to the second simulated speaker arrangement. The method may further include displaying the second simulated speaker arrangement in the speaker arrangement pane of the GUI. The method may further include receiving a second portion selection event corresponding to a portion of a second simulated speaker arrangement displayed in the speaker arrangement pane of the GUI. The method may further include displaying a second pop-up window proximate to the portion of the second simulated speaker arrangement. The second pop-up window may include an initial value of a third property corresponding to the portion. The method may further include receiving a third property adjustment event corresponding to the third property. The method may further include displaying an updated value of the third property based on the third property adjustment event. The method may further include adjusting the second simulated speaker arrangement based on the third property adjustment event. The method may further include receiving a second portion deselection event corresponding to an area of the GUI outside of the second pop-up window. The method may further include closing the second pop-up window in response to the second portion deselection event.

According to an example, the method may further include adjusting an overhead simulation pane of the GUI based on the third property adjustment event. The overhead simulation pane may include an overhead view of a first sound pressure generated by the first simulated speaker arrangement in a model environment. The overhead simulation pane may include an overhead view of a second sound pressure generated by the second simulated speaker arrangement in the model environment.

According to an example, the method may further include adjusting a side simulation pane of the GUI based on the third property adjustment event. The side simulation pane may include a side view of a first sound pressure generated by the first simulated speaker arrangement in a model environment. The side simulation pane may include a side view of a second sound pressure generated by the second simulated speaker arrangement in the model environment.

Other features and advantages will be apparent from the description and the claims.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the various examples.

FIG. 1 is a flowchart for manipulating simulated speaker arrangements, according to an additional example of the present disclosure.

FIG. 2 is a further flowchart for manipulating simulated speaker arrangements, according to an additional example of the present disclosure.

FIG. 3 is a further flowchart for manipulating simulated speaker arrangements, according to an additional example of the present disclosure.

FIG. 4 is a screenshot of a graphical user interface (GUI) for manipulating a simulated speaker arrangement, according to an example of the present disclosure.

FIG. 5 is a further screenshot of a graphical user interface (GUI) for manipulating a simulated speaker arrangement, according to an example of the present disclosure.

FIG. 6 is a further screenshot of a graphical user interface (GUI) for manipulating a simulated speaker arrangement, according to an example of the present disclosure.

FIG. 7 is a further screenshot of a graphical user interface (GUI) for manipulating a simulated speaker arrangement, according to an example of the present disclosure.

FIG. 8A is a screenshot of a graphical user interface (GUI) for manipulating multiple simulated speaker arrangements, according to an example of the present disclosure.

FIG. 8B is a further screenshot of a graphical user interface (GUI) for manipulating multiple simulated speaker arrangements, according to an example of the present disclosure.

FIG. 8C is a screenshot of a graphical user interface (GUI) for manipulating multiple simulated speaker arrangements, according to an example of the present disclosure.

### DETAILED DESCRIPTION

This disclosure generally relates to systems and methods for manipulating arrangements of speakers in a computer-implemented design and simulation environment.

Software for manipulating simulated arrangements of speakers may require the display of a large quantity of information, including simulation results, speaker arrangement properties, and model arrangements. Accordingly, to save screen space and present a well-organized graphical user interface (GUI), the software may utilize pop-up windows to temporarily display and/or modify information. During use of the software, a pop-up window may appear when a user selects a portion of a speaker arrangement, such as a rigging point, an individual speaker, or multiple speakers, by a mouse-click or other selection event. The pop-up window may display a number of adjustable properties for the portion of the arrangement. For example, if a speaker is selected, the pop-up window may allow a user to adjust the gain and/or angle of the speaker. Once a property is adjusted, the simulation results may be automatically updated. The user may close the pop-up window by a mouse-click in an area of the GUI outside of the window, or by another deselection event. By utilizing the pop-up windows, the speaker simulation software allows the user to efficiently adjust the speaker arrangement and simulated results in real-time. Further, utilizing the pop-up windows preserves screen space and may improve computational performance by reducing the number of constantly presented interactive display panes.

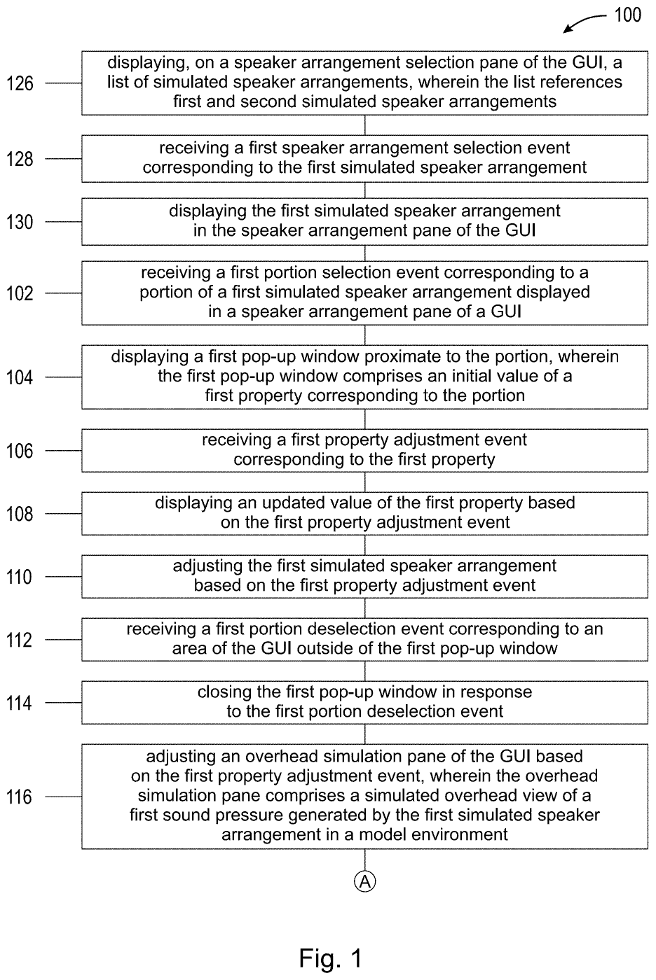

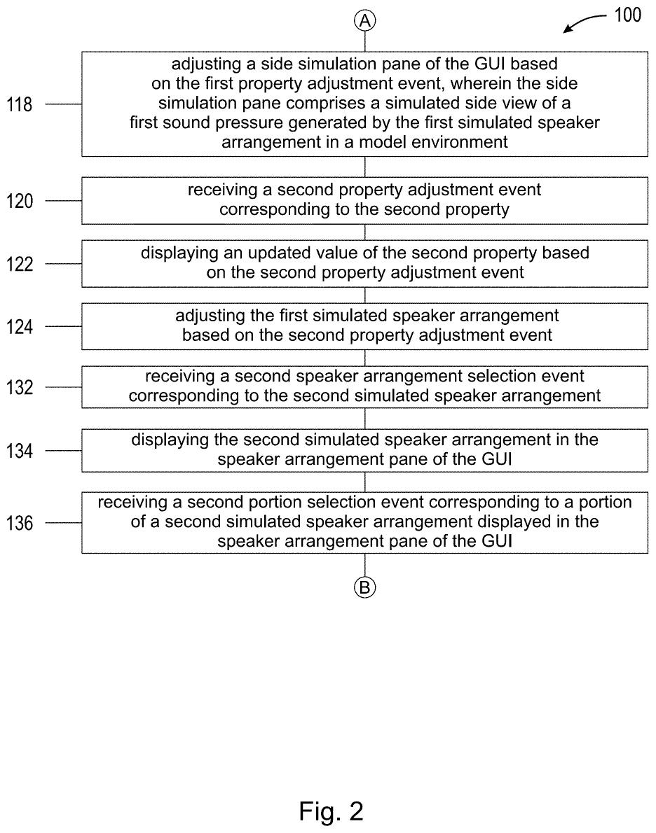

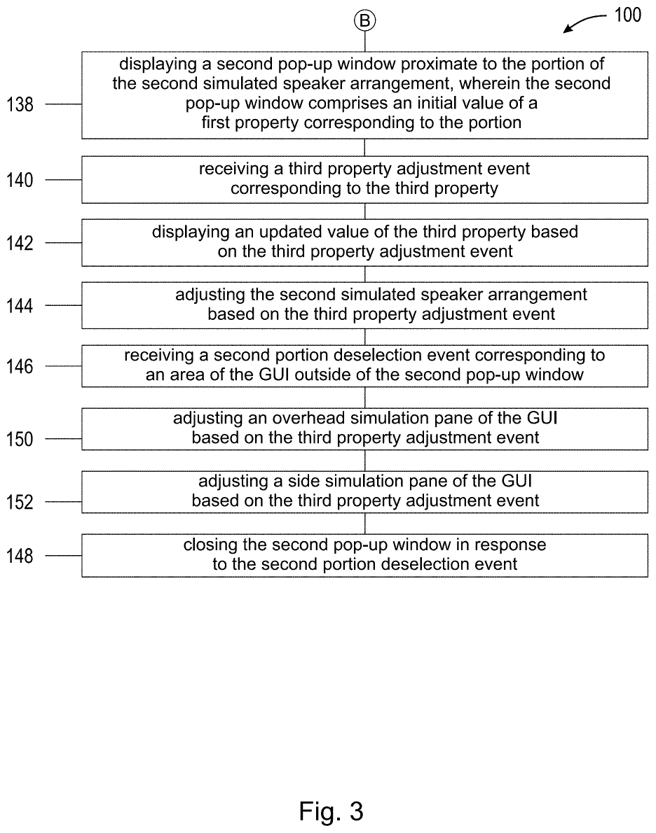

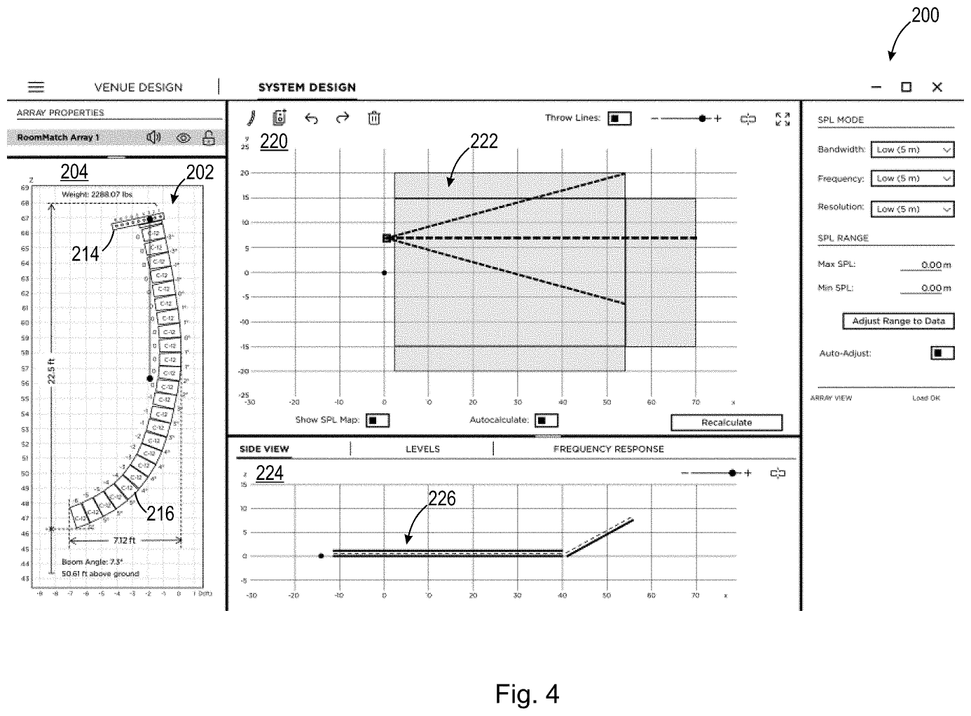

In one aspect, and with reference to FIGS. 1-3, a computer-implemented method 100 for manipulating one or more simulated speaker arrangements is provided. According to this method 100, a GUI 200 for a computer-implemented design and simulation environment, as shown in FIGS. 4-8C, receives various inputs from a user regarding one or more speaker arrangements 202. In response to the inputs, the GUI 200 may adjust one or more display panes in real-time.

FIG. 4 shows an example screenshot of GUI 200 prior to the aforementioned manipulation. The GUI 200 includes a number of display panes. The speaker arrangement pane 204 is positioned on the left side of the GUI 200. The speaker arrangement pane 204 displays a side-view of a first simulated speaker arrangement 202. In FIG. 4, the simulated speaker arrangement 202 is a line array including twenty-four speakers 216 coupled to each other. In FIG. 4, the speakers 216 are twenty-four identical Cohesion 12™ speakers. The speakers 216 are further coupled to a rigging point 214 from which the line array will be hung. The speaker arrangement pane 204 displays a number of properties of the simulated speaker arrangement 202, including height (22.5 feet), weight (2288.07 pounds), depth (7.12 feet), boom angle (7.3 degrees), and distance above ground (50.61 feet).

As shown in FIG. 4, the overhead simulation pane 220 is positioned in the top center of the GUI 200. The overhead simulation pane 220 displays a simulated overhead view of a first sound pressure 222 generated by the first simulated speaker arrangement 202 in a model environment. In an example, the environment may be an arena, stadium, theater, auditorium, performance hall, religious venue, or any other indoor or outdoor setting requiring amplified audio. The first sound pressure generated by the first simulated speaker arrangement 202 is displayed by the three dashed lines of the overhead simulation pane 220.

As also shown in FIG. 4, the side simulation pane 224 is positioned in the bottom center of the GUI 200. Like the overhead simulation pane 220, the side simulation pane 224 displays a simulated side view of a first sound pressure 226 generated by the simulated speaker arrangement 202 in the model environment. The first sound pressure generated by the first simulated speaker arrangement 202 is displayed by the dashed line of the side simulation pane 220. The angle of the lines between x-coordinates 40 and 55 represents an incline in the structure of the environment, such as stadium seating in an arena or theater.

The aforementioned display panes may be sized and/or positioned in any practical arrangement. In further examples, additional display panes may be added to the GUI 200 as needed. In further examples, the aforementioned display panes may be substituted with other panes, or removed from the GUI 200 entirely.

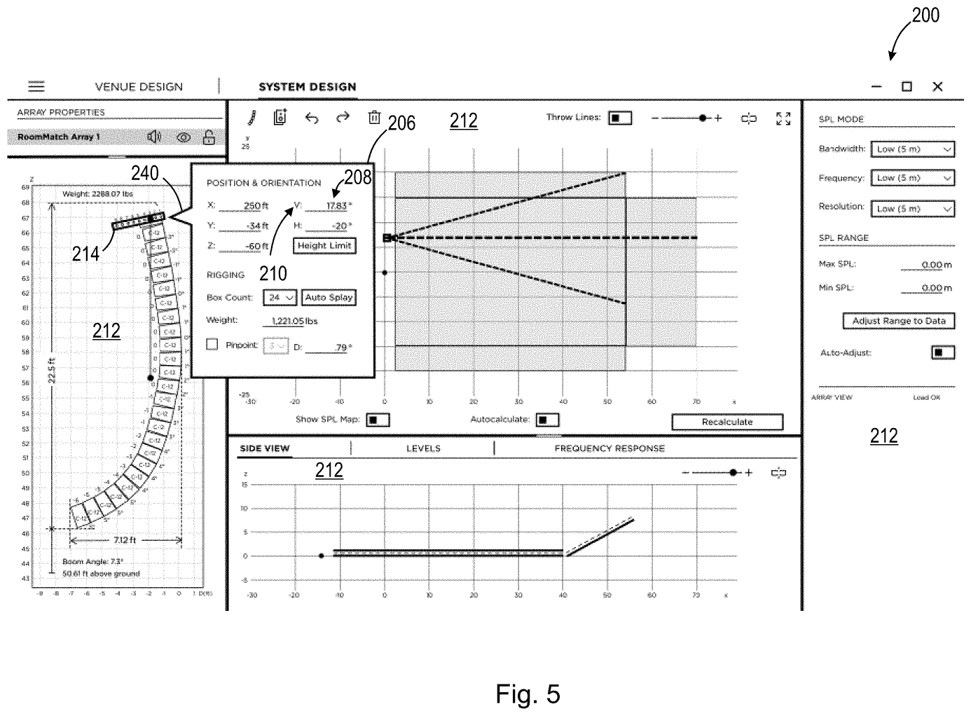

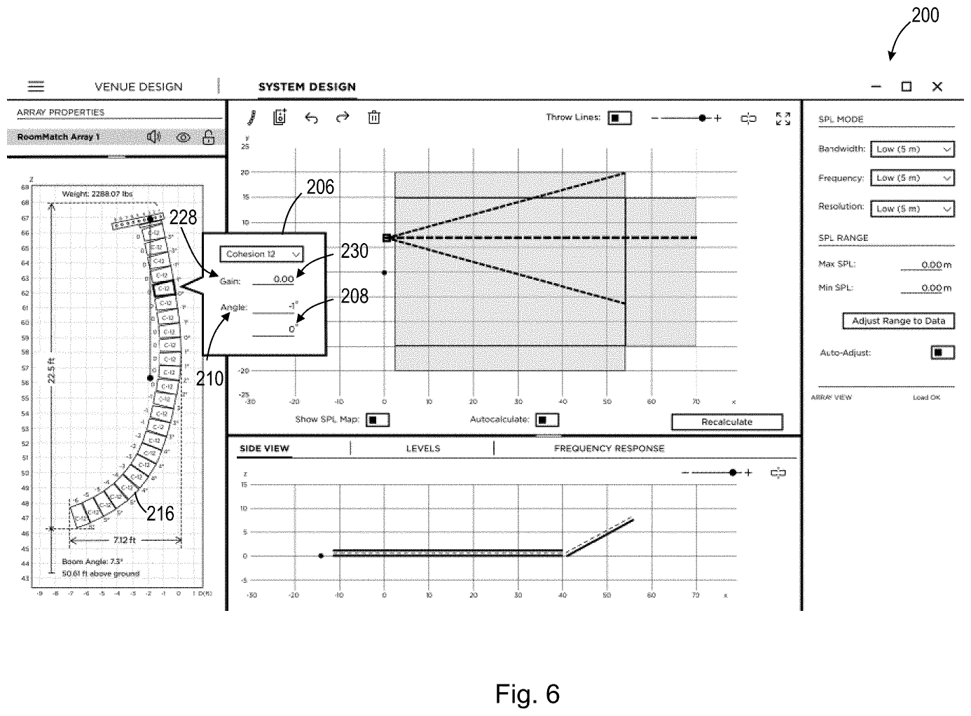

The method 100 may include receiving 102 a first portion selection event corresponding to a portion of a first simulated speaker arrangement 202 displayed in the speaker arrangement pane 204 of the GUI 200. The portion may be a rigging point 214, an individual speaker 216, or a plurality of speakers 218. The first portion selection event may be a mouse-click. The first portion selection event may be a mouse-over-event. The first portion selection event may include one or more key-strokes. The first portion selection event may be any other action or combination of actions which allows the user to choose a portion of the first simulated speaker arrangement 202, such as a mouse-click-and-drag or mouse drag-select. For example, and with reference to FIG. 5, the first portion selection event may be a user clicking on the rigging point 214. In another example, and with reference to FIG. 6, the first portion selection event may be a user positioning a mouse cursor over a speaker 216.

The method 100 may further include displaying 104 a first pop-up window 106. Examples of the first pop-up window 106 are shown in FIGS. 5-7. The first pop-up window 206 may be displayed proximate to the selected portion of the first simulated speaker arrangement 202. The first pop-up window 206 may include a pointer 240 horizontally aligned with the selected portion of the first simulated speaker arrangement 202. The first pop-up window 206 may include an initial value 208 of a first property 210 corresponding to the portion.

According to an example, and with reference to FIG. 5, the portion of the first simulated speaker arrangement 202 may be a rigging point 214. The first property 210 may be selected from a group consisting of x-position, y-position, z-position, box count, vertical angle, horizontal angle, and weight.

According to a further example, and with reference to FIG. 6, the portion of the first simulated speaker arrangement 202 is a speaker 216. As shown in FIG. 6, the speaker 216 selected is the fifth speaker 216 down from the rigging point 214. The first property 210 may be selected from a group consisting of box make, gain, first angle, and second angle. The box make determines the type of speaker to be simulated. In the example of FIG. 6, the speaker is a Cohesion 12™ speaker. The first angle may correspond to the angle formed between the selected speaker 216 and the speaker immediately above. The second angle may correspond to the angle formed between the selected speaker 216 and the speaker immediately below.

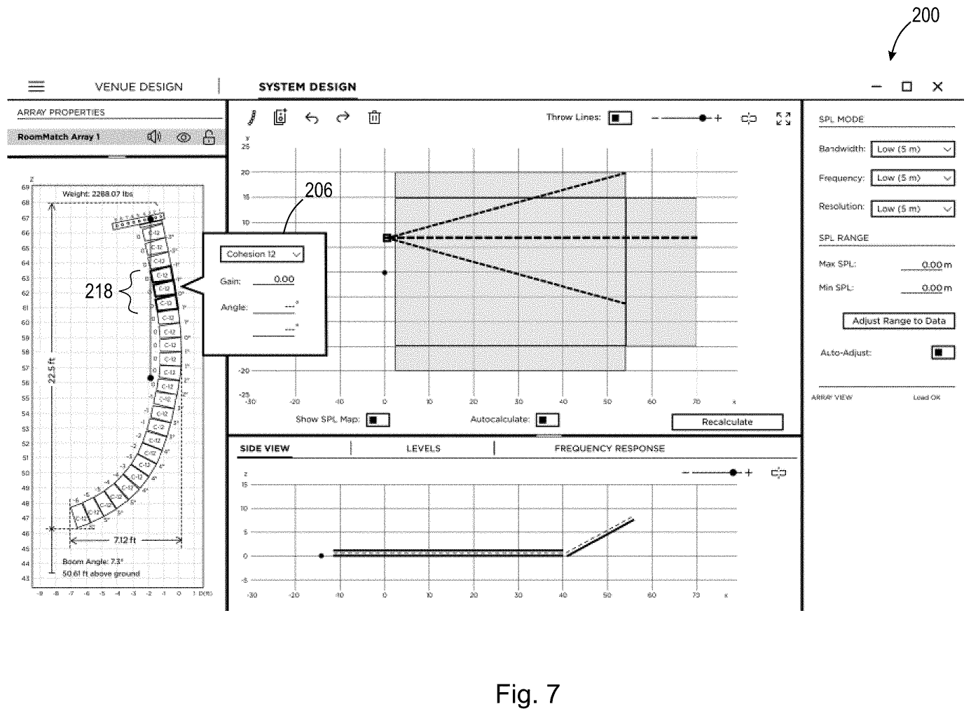

According to a further example, and with reference to FIG. 7, the portion of the first simulated speaker arrangement 202 is a plurality of speakers 218. As shown in FIG. 7, the speakers selected are the fourth, fifth, and sixth speakers down from the rigging point 214. The first property 210 may be selected from a group consisting of box make, gain, first angle, and second angle. By selecting a plurality of speakers 218, the user may manipulate several speakers at once. If the speakers of the plurality 218 have different values for the same property, the first pop-up window 206 may not display a value for that property, nor may the window allow the user to edit that property. For example, in FIG. 7, the speakers of the selected plurality 218 have various values for first and second angle. The values can be seen proximate to the first simulated speaker arrangement 202 in the speaker arrangement pane 204. Accordingly, the values of the first and second angle for the plurality each appear as “ - - - ”, rather than an actual angle value.

The method 100 may further include receiving 106 a first property adjustment event corresponding to the first property 210. The first property adjustment event may include a user entering a new value for the first property via one or more key-strokes. For example, with reference to FIG. 5, the first property adjustment event may include entering a new value for the vertical angle of the rigging point 214. In a further example, and with continued reference to FIG. 5, the first property adjustment event may include selecting a new value for the box count of the simulated speaker arrangement 202 via one or more mouse-clicks. In a further example, and with reference to FIG. 6, the first property adjustment event may include entering a new value of the second angle of the speaker 216.

The method 100 may further include displaying 108 an updated value of the first property 210. The updated value may be based on the first property adjustment event. For example, with reference to FIG. 5, the first property adjustment event may result in the value of the vertical angle of the rigging point 214 to be displayed as 20 degrees. In a further example, and with continued reference to FIG. 5, the first property adjustment event may result in the value of the box count of the simulated speaker arrangement 202 to be displayed as 23. In a further example, and with reference to FIG. 6, the first property adjustment event may result in value of the second angle of the speaker 216 to be displayed as −1.5 degrees.

The method 100 may further include adjusting 110 the first simulated speaker arrangement 202 based on the first property adjustment event. For example, with reference to FIG. 5, if the value of the vertical angle of the rigging point 214 is updated to 20 degrees, the displayed rigging point 214 and the speakers 216 coupled to the rigging point 214 may rotate accordingly. In a further example, and with continued reference to FIG. 5, if the value of the box count is updated to 23, one of the speakers 216, such as the bottom-most speaker, may be removed from the first simulated speaker arrangement 202. In a further example, and with reference to FIG. 6, if the value of the second angle of the speaker 216 is updated to −1.5 degrees, the speaker 216 may rotate accordingly.

According to an example, the method 100 may further include adjusting 116 the overhead simulation pane 220 of the GUI 200 based on the first property adjustment event. This adjustment may include modifying the simulated overhead view 222 of a first sound pressure according to the updated value of the first property 210. The adjustment may occur automatically upon updating the value of the first property 210. The adjustment may also occur upon selection of the “Recalculate” button, or other input by the user.

According to an example, the method 100 may further include adjusting 116 the side view simulation pane 224 of the GUI 200 based on the first property adjustment event. This adjustment may include modifying the simulated side view 224 of a first sound pressure according to the updated value of the first property 210. The adjustment may occur automatically upon updating the value of the first property 210. The adjustment may also occur upon selection of the “Recalculate” button, or other input by the user.

The method 100 may further include receiving 112 a first portion deselection event. The first portion deselection event may correspond to an area 212 (as shown in FIG. 5) of the GUI outside of the first pop-up window 206. For example, with reference to FIG. 5, the first portion deselection event may be a mouse-click or a mouse-over-event corresponding to the speaker arrangement panel 204, the overhead simulation pane 220, or the side simulation pane 224. The first portion deselection event may include one or more key-strokes corresponding to the area 212 outside of the first pop-up window 206. For example, the key-strokes may include a hot-key corresponding to the speaker arrangement panel 204, the overhead simulation pane 220, or the side simulation pane 224.

The method 100 may further include closing 114 the first pop-up window 206 in response to the first portion deselection event. Closing the first pop-up window 206 when the user is not modifying the elements of the first simulated speaker arrangement 202 improves the visual presentation and efficiency of the GUI 200.

According to an example, and with reference to FIG. 6, the pop-up window 206 may further include an initial value 230 of a second property 228 corresponding to the portion. In FIG. 6, the second property 228 is the gain of the selected speaker 216. The initial value 230 of the gain is 0.00 dB. The method 110 may further include receiving 120 a second property adjustment event corresponding to the second property 228. The method 100 may further include displaying 122 an updated value of the second property 228 based on the second property adjustment event. The method 100 may further include adjusting 124 the first simulated speaker arrangement 202 based on the second property adjustment event. Accordingly, the user may modify two or more properties of the selected portion before closing the pop-up window 206 by clicking the area 212 outside of the window 206.

While the aforementioned first simulated speaker arrangement 202 is shown as a line array hung from a rigging point 214, in other examples, the speaker arrangement 202 may include one or more subwoofers. The subwoofers may be simulated as stacked or hung, depending on the application, with particular attention to their weight. In other examples, the speaker arrangement 202 may include one or more point source speakers. The point source speakers may be simulated as stacked or hung, depending on the application.

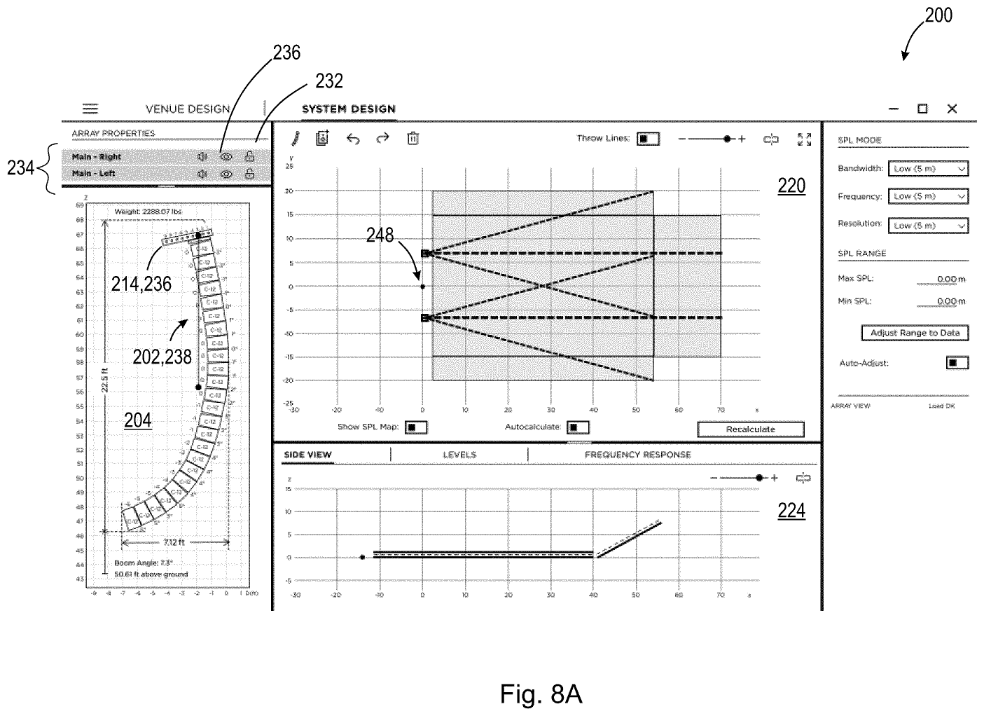

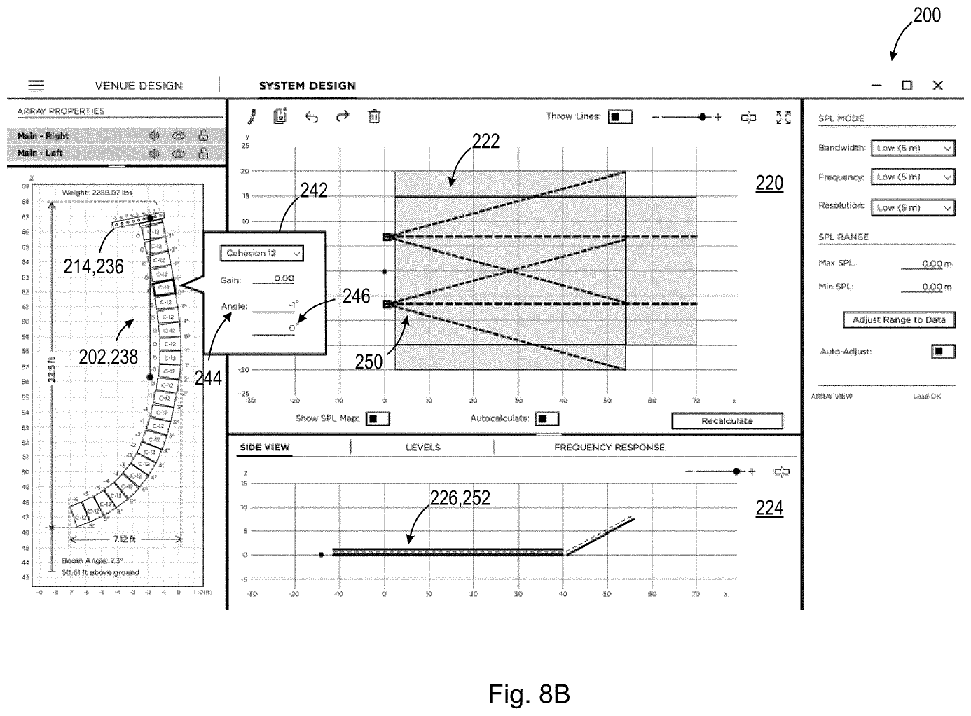

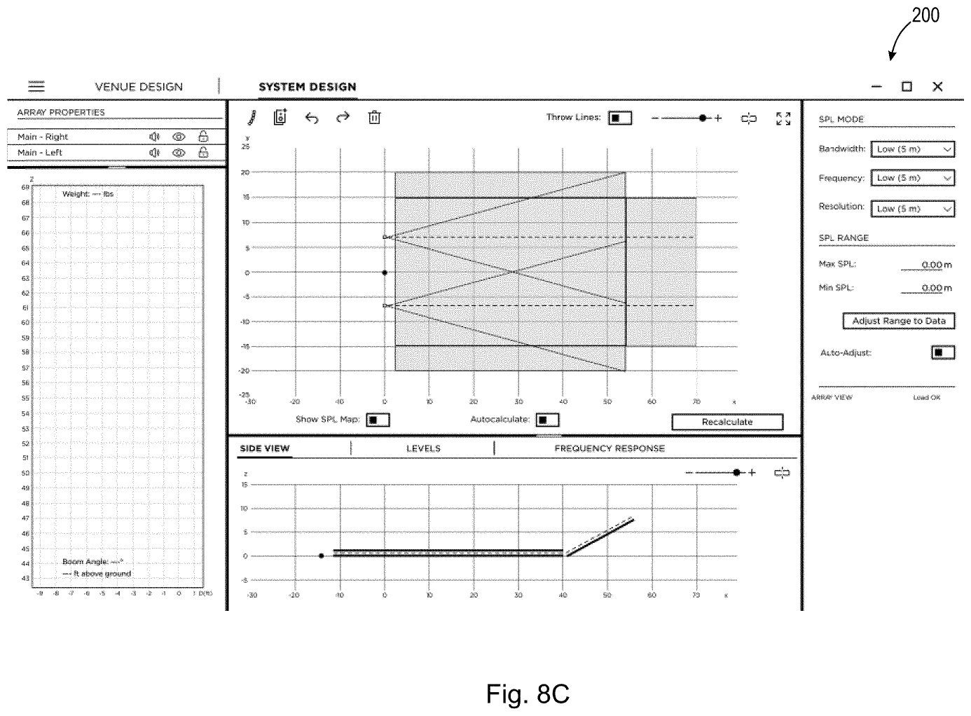

According to an example, and with reference to FIGS. 8A-8C, the method 100 may further include displaying 126, on a speaker arrangement selection pane 232 of the GUI 200, a list of simulated speaker arrangements 234. The user may use this list 234 to choose one or more speaker arrangements to display, simulate, and modify. If more than one speaker arrangement is selected, the user may modify all of the selected arrangements simultaneously. The ability of the user to modify the selected arrangements may be limited to the shared features of the arrangements. In particular, in one example, the user may modify the selected arrangements simultaneously only if the arrangements are identical, both in terms of their components (speakers, rigging point, etc.), as well as the properties (gain, angle, etc.) of those components.

The list 234 may reference the first simulated speaker arrangement 202 and a second simulated speaker arrangement 238. FIGS. 8A and 8B show identical first 202 and second 238 simulated speaker arrangements displayed as a single speaker arrangement when both arrangements are selected simultaneously. By selecting and modifying portions of this single arrangement, the user may modify both simulated speaker arrangements 202, 238 simultaneously. The first 202 and second 238 arrangements include rigging point 214 and rigging point 236, respectively. FIG. 8C shows the GUI 200 with no speaker arrangements selected. Accordingly, neither the first 202 nor second 238 arrangements are displayed in FIG. 8C.

The method 100 may further include receiving 128 a first speaker arrangement selection event corresponding to the first simulated speaker arrangement 202. The first speaker arrangement selection event may include a mouse-click, a mouse-over-event, one or more key-strokes, and/or any other action or combination of actions which allows the user to choose the first simulated speaker arrangement 202 from the list 234. For example, the first speaker arrangement selection event may be a mouse-click on the name (“Main—Left”) of the first simulated speaker arrangement 202 in the speaker arrangement selection pane 232. The method 100 may further include displaying 130 the first simulated speaker arrangement 202 in the speaker arrangement pane 232 of the GUI 100. The speaker arrangement 202 may be displayed following the first speaker arrangement selection event.

According to an example, the method 100 may further include receiving 132 a second speaker arrangement selection event corresponding to the second simulated speaker arrangement 238. The second speaker arrangement selection event may include a mouse-click, a mouse-over-event, one or more key-strokes, and/or any other action or combination of actions which allows the user to choose the second simulated speaker arrangement 238 from the list 234. For example, the second speaker arrangement selection event may be a mouse-click on the name (“Main—Right”) of the second simulated speaker arrangement 238 in the speaker arrangement selection pane 232.

The method 100 may further include displaying 134 the second simulated speaker arrangement 238 in the speaker arrangement pane 204 of the GUI 200. FIG. 8A shows a speaker arrangement pane 204 displaying both the first 202 and second 238 simulated speaker arrangements. In this example, the first 202 and second 238 arrangements are identical speaker arrangements positioned to the left and right of a center point 248, as shown in the simulated overhead view 220 of FIG. 8A.

The method 100 may further include receiving 136 a second portion selection event corresponding to a portion of a second simulated speaker arrangement 238 displayed in the speaker arrangement pane 204 of the GUI 200. The second portion selection event may include a mouse-click, a mouse-over-event, one or more key-strokes, and/or any other action or combination of actions which allows the user to choose a portion of the second simulated speaker arrangement 238.

With reference to FIG. 8B, the method 100 may further include displaying 138 a second pop-up window 242 proximate to the portion of the second simulated speaker arrangement 238. The second pop-up window 242 may include an initial value 246 of a third property 244 corresponding to the portion. In FIG. 8B, the selected portion is the fifth speaker down from the rigging point 236 of the second simulated speaker arrangement 238. The third property is the second angle of the fifth speaker, and has an initial value of 0 degrees.

The method 100 may further include receiving 140 a third property adjustment event corresponding to the third property 244. The third property adjustment event may include a user entering a new value for the third property 244 via one or more key-strokes. The method 100 may further include displaying 142 an updated value of the third property based on the third property adjustment event.

The method 100 may further include adjusting 144 the second simulated speaker arrangement 238 based on the third property adjustment event.

According to an example, and with further reference to FIG. 8B, the method 100 may further include adjusting 150 the overhead simulation pane 220 of the GUI 200 based on the third property adjustment event. The overhead simulation pane 220 may include the overhead view of the first sound pressure 222 generated by the first simulated speaker arrangement 202 in a model environment, such as an arena or theater. The overhead simulation pane may include an overhead view of a second sound pressure 250 generated by the second simulated speaker arrangement 238 in the model environment.

According to an example, and with continued further reference to FIG. 8B, the method 100 may further include adjusting 152 the side simulation pane 224 of the GUI 200 based on the third property adjustment event. The side simulation pane 224 may include the side view of the first sound pressure 226 generated by the first simulated speaker arrangement 202 in the model environment. The side simulation pane 224 may include the side view of a second sound pressure 254 generated by the second simulated speaker arrangement 238 in the model environment.

The method 100 may further include receiving 146 a second portion deselection event corresponding to an area 212 of the GUI 200 outside of the second pop-up window 242. For example, the second portion deselection event may be a mouse-click or a mouse-over-event corresponding to the speaker arrangement panel 204, the overhead simulation pane 220, or the side simulation pane 224. The second portion deselection event may include one or more key-strokes corresponding to the area 212 outside of the second 242 pop-up window. For example, the key-strokes may include a hot-key corresponding to the speaker arrangement panel 204, the overhead simulation pane 220, or the side simulation pane 224.

The method 100 may further include closing 148 the second pop-up window in response to the second portion deselection event. Additional deselection events, such as those described above, may result in the deselection of the first 202 and/or second 238 simulated speaker arrangements. For example, FIG. 8C depicts the GUI 200 with no speaker arrangements selected. In a preferred embodiment, these additional deselection events deselect simulated speaker arrangements following the closing of the pop-up window with a second mouse-click.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of” “only one of” or “exactly one of.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The above-described examples of the described subject matter can be implemented in any of numerous ways. For example, some aspects may be implemented using hardware, software or a combination thereof. When any aspect is implemented at least in part in software, the software code can be executed on any suitable processor or collection of processors, whether provided in a single device or computer or distributed among multiple devices/computers.

The present disclosure may be implemented as a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some examples, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to examples of the disclosure. It will be understood that each block of the flowchart illustrations and/or block diagrams, and combinations of blocks in the flowchart illustrations and/or block diagrams, can be implemented by computer readable program instructions.

The computer readable program instructions may be provided to a processor of a, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various examples of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Other implementations are within the scope of the following claims and other claims to which the applicant may be entitled.

While various examples have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the examples described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific examples described herein. It is, therefore, to be understood that the foregoing examples are presented by way of example only and that, within the scope of the appended claims and equivalents thereto, examples may be practiced otherwise than as specifically described and claimed. Examples of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

What is claimed is:

1. A computer-implemented method for manipulating one or more simulated speaker arrangements, comprising:
receiving a first portion selection event corresponding to a portion of a first simulated speaker arrangement displayed in a speaker arrangement pane of a graphical user interface (“GUI”);
displaying a first pop-up window proximate to the portion, wherein the first pop-up window comprises an initial value of a first property corresponding to the portion;
receiving a first property adjustment event corresponding to the first property;
displaying an updated value of the first property based on the first property adjustment event;
adjusting the first simulated speaker arrangement based on the first property adjustment event;
receiving a first portion deselection event corresponding to an area of the GUI outside of the first pop-up window; and
closing the first pop-up window in response to the first portion deselection event.

2. The computer-implemented method of claim 1, wherein the first portion selection event is a mouse-click.

3. The computer-implemented method of claim 2, wherein the first portion deselection event is a mouse-click.

4. The computer-implemented method of claim 1, wherein the first portion selection event is a mouse-over-event.

5. The computer-implemented method of claim 4, wherein the first portion deselection event is a mouse-over-event.

6. The computer-implemented method of claim 1, wherein the first portion selection event comprises one or more key-strokes.

7. The computer-implemented method of claim 6, wherein the first portion deselection event comprises one or more key-strokes.

8. The computer-implemented method of claim 1, wherein the portion of the first simulated speaker arrangement is a rigging point.

9. The computer-implemented method of claim 8, wherein the first property is selected from a group consisting of x-position, y-position, z-position, box count, vertical angle, horizontal angle, and weight.

10. The computer-implemented method of claim 1, wherein the portion of the first simulated speaker arrangement is a speaker.

11. The computer-implemented method of claim 10, wherein the first property is selected from a group consisting of box make, gain, first angle, and second angle.

12. The computer-implemented method of claim 1, wherein the portion of the first simulated speaker arrangement is a plurality of speakers.

13. The computer-implemented method of claim 12, wherein the first property is selected from a group consisting of box make, gain, first angle, and second angle.

14. The computer-implemented method of claim 1, further comprising adjusting an overhead simulation pane of the GUI based on the first property adjustment event, wherein the overhead simulation pane comprises a simulated overhead view of a first sound pressure generated by the first simulated speaker arrangement in a model environment.

15. The computer-implemented method of claim 1, further comprising adjusting a side simulation pane of the GUI based on the first property adjustment event, wherein the side simulation pane comprises a simulated side view of a first sound pressure generated by the first simulated speaker arrangement in a model environment.

16. The computer-implemented method of claim 1, wherein the pop-up window further comprises an initial value of a second property corresponding to the portion, further comprising:
receiving a second property adjustment event corresponding to the second property;
displaying an updated value of the second property based on the second property adjustment event; and
adjusting the first simulated speaker arrangement based on the second property adjustment event.

17. The computer-implemented method of claim 1, further comprising:
displaying, on a speaker arrangement selection pane of the GUI, a list of simulated speaker arrangements, wherein the list references the first simulated speaker arrangement and a second simulated speaker arrangement;
receiving a first speaker arrangement selection event corresponding to the first simulated speaker arrangement; and
displaying the first simulated speaker arrangement in the speaker arrangement pane of the GUI.

18. The computer-implemented method of claim 17, further comprising:
receiving a second speaker arrangement selection event corresponding to the second simulated speaker arrangement;
displaying the second simulated speaker arrangement in the speaker arrangement pane of the GUI;
receiving a second portion selection event corresponding to a portion of a second simulated speaker arrangement displayed in the speaker arrangement pane of the GUI;
displaying a second pop-up window proximate to the portion of the second simulated speaker arrangement, wherein the second pop-up window comprises an initial value of a third property corresponding to the portion;
receiving a third property adjustment event corresponding to the third property;
displaying an updated value of the third property based on the third property adjustment event;
adjusting the second simulated speaker arrangement based on the third property adjustment event;
receiving a second portion deselection event corresponding to an area of the GUI outside of the second pop-up window; and
closing the second pop-up window in response to the second portion deselection event.

19. The computer-implemented method of claim 18, further comprising adjusting an overhead simulation pane of the GUI based on the third property adjustment event, wherein the overhead simulation pane comprises an overhead view of:
a first sound pressure generated by the first simulated speaker arrangement in a model environment; and
a second sound pressure generated by the second simulated speaker arrangement in the model environment.

20. The computer-implemented method of claim 18, further comprising adjusting a side simulation pane of the GUI based on the third property adjustment event, wherein the side simulation pane comprises a side view of:
a first sound pressure generated by the first simulated speaker arrangement in a model environment; and
a second sound pressure generated by the second simulated speaker arrangement in the model environment.
